(19) United States
(12) Patent Application Publication
(10) Pub. No.: US 2010/0007388 A1
(43) Pub. Date: Jan. 14, 2010

(54) METHOD AND ARRANGEMENT RELATING POWER SUPPLY IN AN ELECTRICAL DEVICE

(75) Inventors: Andreas Wilson, Malmo (SE); Gunnar Klinghult, Lund (SE)

Correspondence Address: HARRITY & HARRITY, LLP, 11350 RANDOM HILLS ROAD, SUITE 600, FAIRFAX, VA, 22030, US

(73) Assignee: SONY ERICSSON MOBILE COMMUNICATIONS AB, Lund (SE)

(21) Appl. No.: 12/170,895

(22) Filed: Jul. 10, 2008

(51) Int. Cl. H03L 7/00

(52) U.S. Cl. 327/143

(57) ABSTRACT

The present invention relates to an arrangement and method for eliminating power failures due to harmful motion. The device includes electrical components that use electrical power, a power source that connects to the electrical components, a motion sensor, and a processing unit. The motion sensor may sense a motion of the device substantially corresponding to free-fall condition, the processing unit may receive a signal from the motion sensor based on the first predetermined motion profile, and the processing unit may generate a signal supplied to at least some of the electrical components to cause a shut down operational mode.

### TECHNICAL FIELD

The present invention relates to an arrangement in a device comprising a free-fall detection arrangement and a power source and a method of preventing power failure.

### BACKGROUND OF THE INVENTION

Communication devices, such as cellular telephones, have become increasingly versatile. For example, cellular telephones today often include applications that allow users to do more than just make and receive telephone calls, such as send/receive text messages, play music, play video games, take pictures, etc. As a result, cellular telephones have become an increasingly common part of every day life for a large number of users.

Due to the mobility of such devices, it is easy to drop the device. One essential problem is on-off problem (software (SW) freezing), which occurs when the device is dropped and the connection between the battery and the device electronics is cut or lost. The problem occurs, mainly because of glitches between the battery connectors and the electrical connectors of the device connecting the electronics to the battery. The time that the connection between the battery and device electronics is lost, may be assumed to be on the order of 1-10 ms, for example.

Typically, when such devices are in “sleep mode,” the current consumption is on the order of 1-2 mA, for example.

In sleep mode, the voltage can drop to 3.0V, for example, before the device intelligence shuts down the device. The software shutdown at 3.2V, for example, is too slow to react at times described above.

Recently, mobile handsets with motion sensing MEMS (Micro-electro-mechanical systems) devices, such as accelerometers, have been introduced on the market.

Accelerometers are being integrated into some mobile handsets to enable such applications as intelligent user interfaces that let users input commands through gestures; indoor GPS functionality (which calculates the movement and direction of the device after contact is broken with a GPS satellite); game controls; and intelligent power consumption (which automatically shuts off circuitry when it is not needed).

FIG. 1 illustrates a device 100, such as a mobile phone, which includes a housing 101, a power source, such as a battery 110, an accelerometer 120, and controlling electronics 130.

Of course the device comprises other electrical circuits, e.g., transceiver and interface circuits, in case of a mobile phone, well known to a skilled person, which are not described herein.

### SUMMARY OF THE INVENTION

The present invention introduces a novel solution for a power interruption control, for example, due to dropping of the device and/or unwanted acceleration, which eliminates the problems with on/off problems and software freezing.

Embodiments according to present invention may use already existing hardware and/or additional hardware. Embodiments may improve the robustness and quality of the mobile devices from a user point of view and may reduce the return rate.

Thus, a method is provided in a device comprising at least one electrical component configured to be supplied with power from a power source, said device comprising a motion sensor to provide a motion profile of said device and a processing unit. The method comprises: sensing a motion of said device by said motion sensor to provide a first motion profile of said device, generating a signal corresponding to said sensed first motion profile, and providing a signal to said at least one of said electrical component to resume a first operational mode if said first motion profile differs from a predetermined motion profile. Most preferably, the first operational mode is a shut off state.

The method may further comprise sensing a motion of said device corresponding to a second predetermined motion profile, generating a signal corresponding to said second predetermined motion profile, and providing a signal to said at least one electrical components t resume a second operational mode. Thus, the second operational mode is a normal operational mode. Preferably, the predetermined motion profile is substantially zero (0) g motion the first motion profile is a free-fall motion and the second motion profile is a substantially zero (0) g motion.

The invention also relates to a device comprising: an electrical component configured to be supplied with power, a power source for supplying said components, a motion sensor, a processing unit,. The motion sensor is configured to sense a motion of said device corresponding to a first motion profile, the processing unit is configured to receive a signal from said motion sensor corresponding to said first motion profile, and the processing unit is further configured to compare said signal corresponding to said first motion profile with a predetermined motion profile and generate a signal supplied to said electrical component to resume a first operational mode. The first operational mode is shut off state.

The device may further comprise a capacitive element for maintaining power during said first operational mode. Preferably, the power supply is a battery.

Advantageously, the electrical component comprises radio receiver and/or transmitter. The device may further comprise a communication portion for communication with a communication network. Preferably, the device may further comprise a housing, a display, control buttons and a keypad.

In one advantages embodiment, the motion sensor is further configured to sense a motion of said device corresponding to a second motion profile, the processing unit is configured to receive a signal from said motion sensor corresponding to said second motion profile, and said processing unit is further configured to compare said signal corresponding to said second motion profile with a predetermined motion profile and generate a signal supplied to said electrical component to resume a second operational mode. The second operational mode is thus a normal operational mode.

Preferably, the device may be one of a radiotelephone; a personal communications system (PCS) terminal combining a cellular radiotelephone with data processing, a facsimile, and data communications capabilities; a personal digital assistant (PDA), a camera, a sound recorder and/or global positioning system (GPS) receiver; a laptop; or a GPS device.

### BRIEF DESCRIPTION OF THE DRAWINGS

The accompanying drawings, which are incorporated in and constitute a part of this specification, illustrate an embodiment of the invention and, together with the description, explain the invention. In the drawings:

FIG. 1 illustrates schematically a state of the art solution;

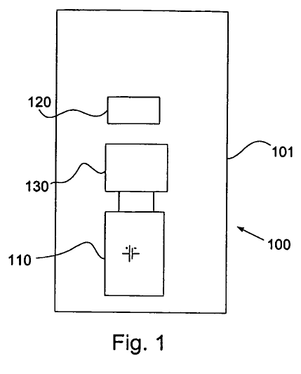

FIG. 2 illustrates schematically an embodiment of a device according to the present invention;

FIG. 3 is a flow diagram of the steps of the method according to the present invention; and

FIG. 4 is graphical test results from an embodiment according to the invention.

### DETAILED DESCRIPTION

A “device,” as the term is used herein, is to be broadly interpreted to include a radiotelephone; a personal communications system (PCS) terminal that may combine a cellular radiotelephone with data processing, a facsimile, and data communications capabilities; a personal digital assistant (PDA) that can include a radiotelephone, pager, Internet/intranet access, web browser, organizer, calendar, a camera (e.g., video and/or still image camera), a sound recorder (e.g., a microphone), and/or global positioning system (GPS) receiver; a laptop; a GPS device; a camera (e.g., video and/or still image camera); a sound recorder (e.g., a microphone); and any other computation or communication device capable of processing, storing, and/or displaying media, such as a personal computer, a home entertainment system, a television, etc.

An “on/off” as the term is used herein, is to be broadly interpreted to include power supply failure or reduction.

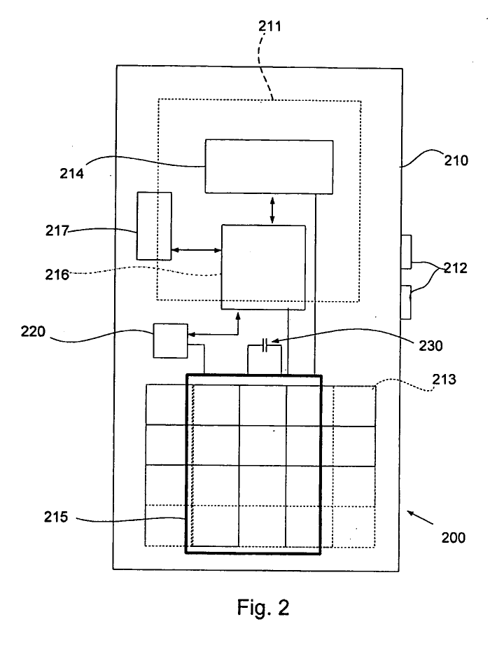

As shown in FIG. 2, an exemplary device 200 may include a housing 210, a display 211, control buttons 212, a keypad 213, a communication portion 214, a battery 215 (or consumable power source), a microprocessor 216 (or data processing unit), a memory unit 217, and a motion detecting sensor 220, such as an accelerometer. Housing 210 may protect the components of device 200 from outside elements. Display 211 may provide visual information to the user. For example, display 211 may provide information regarding incoming or outgoing calls, media, games, phone books, the current time, etc. Control buttons 212 may permit the user to interact with device to cause device to perform one or more operations. Keypad 213 may include a standard telephone keypad. Motion detecting sensor 220 may enable applications such as commands input through gestures, indoor GPS functionality, game controls; and intelligent power consumption.

Communication portion 214 may include parts (not shown) such as receiver, transmitter, antenna etc., for establishing and performing communication with one or several communication networks.

When a free-falling condition (e.g., substantially zero g) is detected by motion detecting sensor 220, e.g., the accelerometer, a signal may be sent to processing unit 216, which may be configured to generate an interrupt signal according to instructions stored in memory unit 217.

Processing unit 216 may instruct the running applications (programs) to shut down, based on the interrupt signal, e.g., transmitters, LEDs, memory access, etc., and go to “sleep mode” with its low current consumption and/or an alternative mode of operation.

After the phone has stopped and/or substantially changed its motion (e.g., come to rest the ground, be set in motion in a different direction), processing unit 216 may receive a signal from motion detecting sensor 220, e.g., the accelerometer, and thus may restore the applications to the previous state, e.g., restore connections (transmitters), switch on LEDs, access memory, etc.

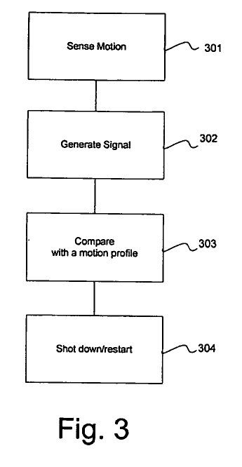

Calculations and simulations reveal to the inventors that it is possible to maintain a voltage not dropping below, e.g., about 3 V, and thereby keep the device running with a capacitance 230 typically used in the electronic design. FIG. 3 illustrates a chart over the simulation result. This capacitance may be a part of normal design and is used for decoupling mainly at voltage regulators and DC/DC converters.

Thus, FIG. 3 illustrates an exemplary method for performing embodiments of the invention with reference to components shown in FIG. 2: motion sensor 220 may sense (act 301) the motion of device 200, and transmit (act 302) a signal to processing unit 216. The signal may correspond to the sensed (absolute) sensor value and/or a difference (delta) (act 303) between a sensed value and a predetermined stored (threshold) value. If the signal corresponds to a sensed value, processing unit 216 may compare (act 303) the value with a predetermined value stored in memory 217. If it is determined that the sensed motion is substantially a free-falling motion, some or all of the electrical components may be instructed (act 304) to power down and/or shut off.

Motion sensor 220 may be configured to continue to sense (act 301) motion associated with device 200, and transmit (302) the signal to processing unit 216. The signal may correspond to the sensed sensor value and/or a difference (act 303) between a predetermined stored (threshold) value. If the signal corresponds to a sensed value, processing unit 216 may compare (act 303) the value with a predetermined value stored in memory 217. If it is determined that the sensed motion is not free-falling, e.g., at rest, in normal use, etc., the electrical components may be instructed (act 304) to power up and resume functionality.

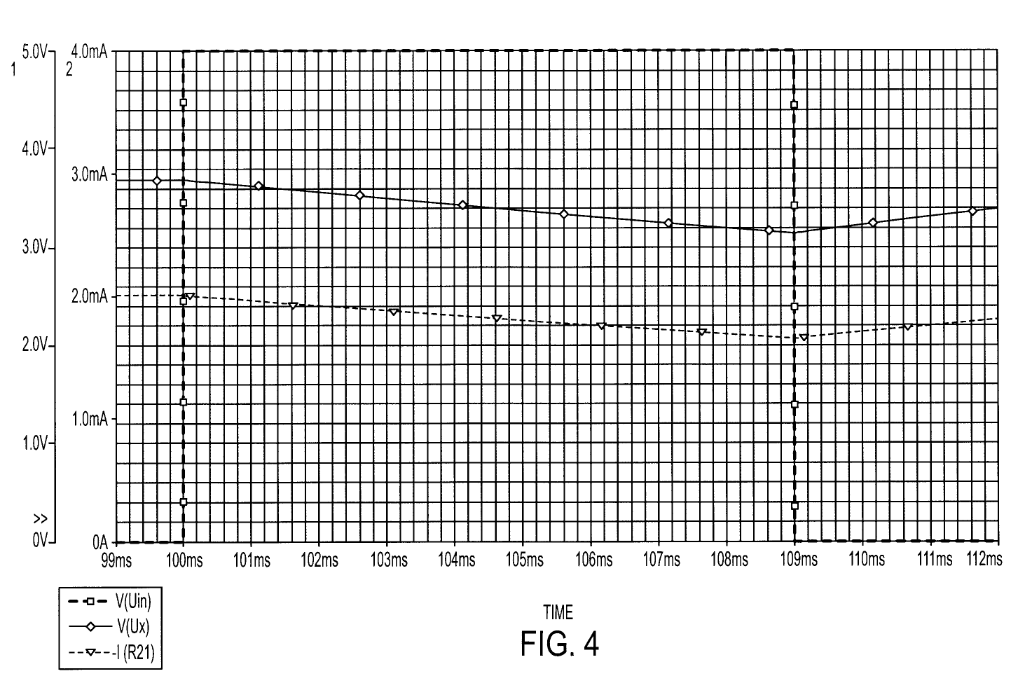

The simulations result given as an example in FIG. 4, shows battery 215 disconnected at 100 ms and connected again at 109 ms (9 ms of disconnection), the voltage drop at phone electronic (on top, starting point=3.7 V, drops to 3.15 V), the current to the phone electronic (at the bottom, starting point=2.0 mA). A 30 uF capacitor was used. This capacitance is equal to what typically may be used connected to battery 215 on the electronic side. Other capacitance may be used.

In performing embodiments of the invention, the effect of the power failure is eliminated and the circuits needing power for their operation are maintained operating.

It should be noted that the word “comprising” does not exclude the presence of other elements or steps than those listed and the words “a” or “an” preceding an element do not exclude the presence of a plurality of such elements. It should further be noted that any reference signs do not limit the scope of the claims, that the invention may be implemented at least in part by means of both hardware and software, and that several “means,” “units,” and/or “devices” may be represented by the same item of hardware.

The above mentioned and described embodiments are only given as examples and should not be limiting to the present invention. Other solutions, uses, objectives, and functions within the scope of the invention as claimed in the below described patent claims should be apparent for the person skilled in the art. Accelerations less than or greater than free-fall that are determined to be sufficient to cause power disruption may be detected and used for triggering the protective operations described above with respect to free-fall conditions. Such accelerations may be peculiar to particular designs, components, housing, shock-absorption features, etc.

What is claimed is:

1. In a device including at least one electrical component configured to be supplied with power from a power source, the device including a motion sensor to provide a motion profile of the device and a processing unit, a method comprising:
sensing a motion of the device by the motion sensor to provide a first motion profile of the device;
generating a signal corresponding to the first motion profile; and
providing a signal to the at least one electrical component to assume a first operational mode when the first motion profile differs from a predetermined motion profile.

2. The method of claim 1, wherein the first operational mode is a shut off state.

3. The method of claim 1, further comprising:
sensing a motion of the device corresponding to a second predetermined motion profile;
generating a signal corresponding to the second predetermined motion profile; and
providing a signal to the at least one electrical component to resume a second operational mode.

4. The method of claim 3, wherein the second operational mode is a normal operational mode.

5. The method of claim 1, wherein the predetermined motion profile is substantially zero (0) g motion.

6. The method of claim 1, wherein the first motion profile is a state of free-fall.

7. The method of claim 3, wherein the second motion profile is a substantially zero (0) g motion.

8. A device comprising:
at least one electrical component configured to be supplied with power;
a power source for supplying the at least one electrical component;
a motion sensor configured to sense a motion of the device corresponding to a first motion profile; and
a processing unit, wherein the processing unit is configured to receive a signal from the motion sensor corresponding to the first motion profile, and compare the signal corresponding to the first motion profile with a predetermined motion profile and generate a signal supplied to the electrical component to resume a first operational mode.

9. The device of claim 8, wherein the first operational mode is a shut off state.

10. The device of claim 8, further comprising:
a capacitive element to maintain power during the first operational mode.

11. The device of claim 8, wherein the power supply is a battery.

12. The device of claim 8, wherein the at least one electrical component comprises a radio receiver and/or a transmitter.

13. The device of claim 8, further comprising:
a communication portion to enable communication via a communication network.

14. The device of claim 8, further comprising:
a housing;
a display;
control buttons; and
a keypad.

15. The device of claim 8, wherein
the motion sensor is further configured to sense a motion of the device corresponding to a second motion profile,
the processing unit is configured to receive a signal from the motion sensor corresponding to the second motion profile, and
the processing unit is further configured to compare the signal corresponding to the second motion profile with a predetermined motion profile and generate a signal supplied to the electrical component to resume a second operational mode.

16. The device of claim 8, the first operational mode is a normal operational mode.

17. The device of claim 8, wherein the device comprises a radiotelephone; a personal communications system (PCS) terminal combining a cellular radiotelephone with data processing, a facsimile, and data communications capabilities; a personal digital assistant (PDA), a camera, a sound recorder and/or global positioning system (GPS) receiver; a laptop; or a GPS device.
